(19) United States
(12) Patent Application Publication
(10) Pub. No.: US 2005/0220232 A1
(43) Pub. Date: Oct. 6, 2005

(54) Circuit arrangement and a method to transfer data on a 3-level pulse amplitude modulation (PAM-3) channel

(75) Inventors: Mika Kunnari, Tampere (FI); Juha H. Nurmi, Salo (FI); Kaj Saarinen, Turku (FI)

Correspondence Address: HARRINGTON & SMITH, LLP, 4 RESEARCH DRIVE, SHELTON, CT, 06484-6212, US

(73) Assignee: Nokia Corporation

(21) Appl. No.: 10/815,887

(22) Filed: Mar. 31, 2004

(51) Int. Cl. H03K 7/02; H03K 9/02; H04L 25/49

(52) U.S. Cl. 375/353

(57) ABSTRACT

A mobile station (10) includes a plurality of sub-assemblies coupled together by a plurality of data communication buses (22) connected to ports (20). At least one port includes a Multi-level Analog Signaling (MAS) circuit arrangement that includes a transmitter to encode data bits represented by multi-level analog signals. A data communications bus that couples the transmitter to a receiver in another port includes at least two multi-level, possibly differential signal buses for conveying the encoded data bits such that, on each multi-level signal bus, during each data bit period the signal level is required to change from a first signal level to a second, different signal level. The transmitter indicates a data boundary, such as the beginning or the end of multi-bit frame, to the receiver by holding one of the multi-level signal buses of the at least two signal buses at the same level for at least two consecutive bit periods.

### TECHNICAL FIELD

This invention relates generally to asynchronous communications links that use multi-level analog signaling and, more specifically, relates to multi-level pulse amplitude modulation (PAM), in particular PAM-3 (PAM with three amplitude levels), and even more specifically relates to the use of the PAM-3 technique for communication between logical entities within a device, such as a mobile communications device.

### BACKGROUND

Multi-level analog signaling (MAS) is used in Ethernet (10 Gigabit Ethernet) and other applications. Various MAS techniques include T-Waves, Quadrature Amplitude Modulation (QAM) and, of most interest to this invention, PAM, in particular PAM-3 (other PAM techniques, such as PAM-5, are also known in the art). In general, the transmission of different amplitude levels over a serial asynchronous link can be used to reduce electromagnetic interference and other problems, and is a well known technique.

If an oscillator is required at the receiver for data recovery, then the ability to reduce receiver power consumption during idle periods (static power consumption) is compromised, as the oscillator will typically remain powered on at least for some part of the idle period. If powered down or off, then some finite amount of time is required to re-power and settle the oscillator circuitry when the idle period ends (i.e., when data reception begins again). Further, and depending on the architecture of the system, there may be a plurality of instances of the receiver circuitry, each requiring its own associated oscillator. As may be appreciated, in many applications it is desirable to minimize power consumption, circuit complexity and cost. While the clock signal could be transmitted through a separate line from the transmitter to the receiver, this technique also adds cost and complexity to the system. For example, 4-level logic (with a separate clock line) is used in, for example, RAMBUS memory systems, with an option to use only the two middle amplitude levels.

A publication of interest is IEEE Journal of Solid State Circuits, Vol 29, No 9, September 1994: Crister Svensson and Jiren Yuan, “A 3-Level Asynchronous Protocol for a Differential Two-Wire Communication Link”. This publication describes a technique that uses multi-level amplitude signaling in such a way that there is no need to provide an oscillator at the receiver. In the 3-level signaling method of Svensson et al. the symbol 0 is represented by a change from state S(i) to S(I+1), and the symbol 1 is represented by a change from state S(i) to S(I−1).

Another publication of interest is “Ternary Physical Protocol for Marilan, A Multiple-Access Ring Local Area Network”, R. J. Kaliman et al., Electrical Engineering Dept., Univ. of Maryland, College Park, Md., pp. 14-20, 1988. FIGS. 4(a) and 4(b) show symbol encoding examples for an exemplary binary sequence and a ternary non-return to zero (NRZ) representation thereof, respectively. In the approach of Kaliman et al. the ring local area network physical layer uses the ternary NRZ code that is suitable for asynchronous transmission, and the code symbols assume values in the balanced ternary set {−1,0,1}. To detect a clock signal, a transition must occur at the end of every bit period and, consequently, two consecutive channel symbols must take different ternary values (as shown in FIGS. 4(a) and 4(b) for the repeats of the binary 1 and binary zero bits).

Communication between two logical entities or peripherals (within the same device) is typically accomplished via a dedicated interface, which may be a parallel or a serial interface. Such interfaces have been implemented using CMOS-based single-ended or low voltage differential signaling (LVDS)-based signaling. The dedicated interface can be defined as a physical connection between devices and a protocol, which is assumed to be known at both devices.

A general reference with regard to LVDS is Application Note 971, “An Overview of LVDS Technology“, AN-971, Syed B. Huq and John Goldie, National Semiconductor Corporation (1998).

Parallel interfaces (such as those implemented with single-ended CMOS) typically use 2 to N signals for data, with one being used for a clock signal and from one to M control signals being used for creating a protocol. The clock signal is used to sample received data, and the control signals are used to create the data transfer protocol (i.e., define when a transmission begins and when it ends, etc.).

One problem with this conventional approach is that is requires numerous integrated circuit (IC) pins at each device. Also, the maximum transmission speed is limited in parallel interfaces due to electromagnetic interference (EMI) problems caused by the transmission of high speed signals.

Conventional serial interfaces typically use from one to about a maximum of four signals for data transfer. If only one signal is used, the clock is embedded in the data. The use of a (single-ended) serial interface solves the problem of excess pin usage requirements, but the maximum transmission speed is limited. Using differential signalling (e.g., LVDS) the transmission speed can be improved (to about 400 Mbps with current technology).

However, a problem that remains in the use of the serial protocol is how to indicate when a transmission starts and ends. For this purpose, dedicated control signals can be used. However, with this approach the data rate versus pin count ratio is not optimal, due to the use of the additional pins for the control signals.

In summary, the parallel interface uses additional signal paths to define the transmission protocol. For serial interfaces, different methods have been used to define the transmission protocol. In some cases additional signals have been added to define the protocol, or additional latency has been added between transmitted packets. In some cases special synchronization codes have been used.

None of these conventional approaches provides an optimal solution to the problem of providing a high speed and efficient interface that has a good data rate versus pin count ratio, while simultaneously solving the synchronization problem.

### SUMMARY OF THE PREFERRED EMBODIMENTS

The foregoing and other problems are overcome, and other advantages are realized, in accordance with the presently preferred embodiments of these teachings.

The invention addresses and solves at least two problems that are encountered with current interfaces. When compared to the parallel interface, the invention uses fewer signals for communication. When compared to the serial interface, the invention solves the synchronization problem (defines the start/end of transmission), without adding additional signals to the interface.

A mobile station includes a plurality of sub-assemblies coupled together by a plurality of data communication buses connected to ports. At least one port includes a Multi-level Analog Signaling (MAS) circuit arrangement that includes a transmitter to encode data bits represented by multi-level analog signals. A data communications bus that couples the transmitter to a receiver in another port includes at least two multi-level signal buses (either differential or single-ended) for conveying the encoded data bits such that, on each multi-level signal bus, during each data bit period the signal level is required to change from a first signal level to a second, different signal level. The transmitter indicates a data boundary, such as the beginning or the end of multi-bit frame, to the receiver by holding one of the multi-level signal buses of the at least two multi-level signal buses at the same level for at least two consecutive bit periods.

Also disclosed is a MAS method that includes encoding data bits represented by multi-level analog signals; transmitting the encoded data bits over at least two multi-level signal buses between a transmitter and a receiver such that, on each multi-level signal bus, during each data bit period the signal level is required to change from a first signal level to a second, different signal level; and indicating a data boundary to the receiver by holding one of the multi-level signal buses at the same level for at least two consecutive bit periods.

### BRIEF DESCRIPTION OF THE DRAWINGS

The foregoing and other aspects of these teachings are made more evident in the following Detailed Description of the Preferred Embodiments, when read in conjunction with the attached Drawing Figures, wherein:

FIG. 1A is a simplified block diagram of a mobile station having sub-assemblies connected by buses via ports;

FIG. 1B shows a dual differential bus connecting two of the ports of FIG. 1A and having a D0 (Master), D1 configuration;

FIG. 2A illustrates a frame;

FIG. 2B shows a signaling method using the D0, D1 differential driver/receiver configuration of FIG. 1B;

FIG. 3 illustrates a data transfer frame structure; and

FIG. 4 illustrates a presently preferred read operation using the D0, D1 differential driver/receiver configuration of FIG. 1B, where the D0 channel is used as a clock channel for data bits transmitted on the D1 channel.

### DETAILED DESCRIPTION OF THE PREFERRED EMBODIMENTS

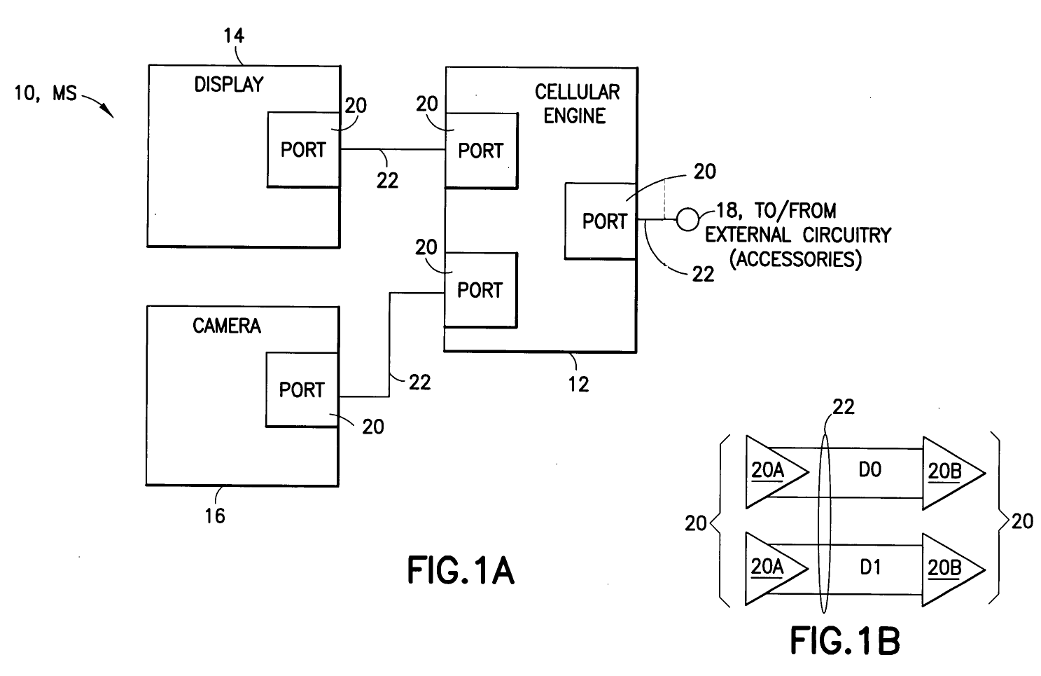

FIG. 1A is a simplified block diagram of a mobile device or mobile station 10, such as a cellular telephone, having a plurality of sub-assemblies. The sub-assemblies may be, by example, a cellular engine 12, a display 14 and a camera 16 that are connected by buses 22 (implemented with cables or stripline pairs) via ports 20. The cellular engine 20 may also be coupled to external components, such as an accessory or accessories 18, via another port 20 and bus 22.

It should be noted that the embodiment of FIG. 1A is exemplary, in that there may be more than or fewer than the illustrated number and types of sub-assemblies. Furthermore, in another embodiment a hub architecture may be employed, where the ports 20 and buses 22 are arranged into a signal line concentrator such that, as an example, the display 14, camera 16 and cellular engine 12 would each be connected together via a hub sub-assembly (the cellular engine 12 may in this case have only one port 20 for connection to the hub, instead of the three ports 20 illustrated in FIG. 1A).

In the preferred embodiment the ports 20 and buses 22 are based on a Multi-level Analog Signaling (MAS) technique, in particular a PAM-3 technique, where every symbol transmitted contains information of at least one bit.

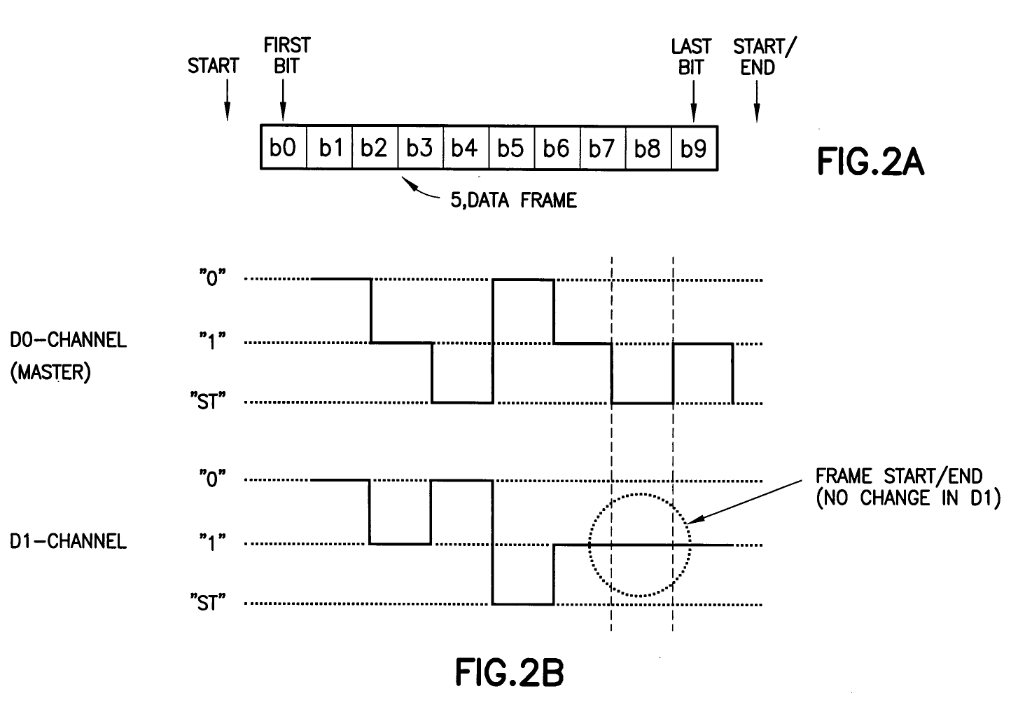

FIG. 1B shows a presently preferred embodiment of a dual differential bus 22 connecting two of the ports 20 of FIG. 1A that have a D0 (Master), D1 configuration. That is, the presently preferred embodiment of the bus 22 uses four signal lines configured as two differential line pairs for data transfer using PAM-3 signalling. The first pair of lines, and the associated driver amplifiers 20A and receiver amplifiers 20B, can be denoted as D0 or as the “master⇄, while the other can be denoted as D1 or as a “slave”. When a data frame 5 begins, as shown in FIGS. 2A and 2B, the signal levels change only in the master channel (D0), while the slave channel (D1) holds its value to indicate the start of the frame 5. When both D0 and D1 change it indicates that data bits are being transmitted, in this case two bits in parallel, with one bit being transmitted on D0 and the other on D1. When the entire frame 5 has been sent, the slave channel (D1) again holds its value and master channel changes its value indicating the end of the frame. The duration of the stable period of D1 can be from one recovered clock cycle to several clock cycles. If a new frame is to be sent the data transfer can continue as for the first frame and, when all data is sent, both the master and slave channels (D0 and D1) remain stable.

Note that the multi-level signal bus 22 need not be a differential bus, and that single-ended, multi-level bus embodiments can be employed as well to implement the teachings of this invention.

It is assumed that the port 20, or some agency connected to the port 20, is operable for encoding data to be transmitted into the preferred PAM-3 MAS format, for deriving a clock from the received signals, for decoding the encoded data, and for indicating the presence of data boundaries in accordance with the invention.

Note in FIG. 2B that, except for holding D1 at the same level for at least two consecutive bit periods, that the signal lines D0 and D1 change state every bit time between the “0”, “1” and “strobe” (ST) states or levels. That is, in the PAM-3 channel of most interest to this invention the data is sent using three logic levels. When a logical one bit is sent, the signal level changes to “1” and in case of sending a logical zero bit, the signal level changes to “0”. If the signal level is a “0” or a “1”, and if the next consecutive bit has the same value, the logic level is changed to the strobe level “ST” to generate a change in the signal line, so that a clock signal can be recovered at the receiver. In accordance with this invention, holding D1 at the same level for at least two consecutive bit periods signals the receiver of the presence or occurrence of a data boundary, in this case either the beginning or end of the frame 5.

The protocol implementation assumes that the transmitting device (e.g., the cellular engine 12 of FIG. 1A) generates the frame start condition before starting the transmission of a frame 5, and that the receiving peripheral (e.g., the display 14 of FIG. 1A) recognizes the frame start condition, and that it can then track when both channels (D0 and D1) begin to change, thereby indicating the actual start of the data transfer.

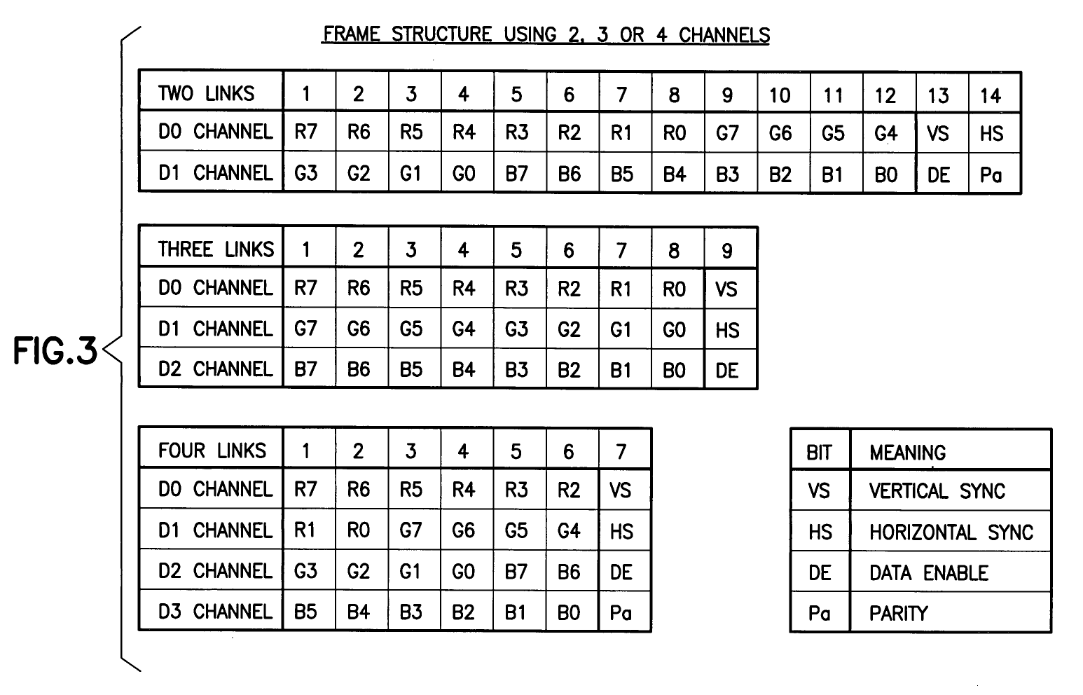

The structure of the frame 5 shown in FIG. 2A can vary in length. One suitable frame size, when using the two differential pairs for the bus 22, is 28 bits, where 24 bits are for data, three are for control purposes, and one is for error checking (e.g., a parity bit). This type of frame structure is particularly applicable for use with displays 14 and cameras 16, that transfer 24-bit data (8-bit RGB data), although it can be adapted for use with just about any type of peripheral device. If more capacity is needed, the number of channels can be expanded, as is shown in FIG. 3 for the case of three differential pairs (D0, D1, D2 channels) and four differential pairs (D0, D1, D2, D3 channels).

In the non-limiting example of FIG. 3 the bits: R7-R0 represent 8-bits of red video channel data; G7-G0 represent 8-bits of green video channel data; B7-B0 represent 8-bits of blue video channel data; VS (Vertical Sync), HS (Horizontal Sync) and DE (Data Enable) are display 14 related control bits representing active frame, active line and data/command (related to the 24 data/command bits), respectively; and Pa is the parity bit for the other 27-bits. The data/control signal organization is shown for two, three and four link high speed serial interface embodiments.

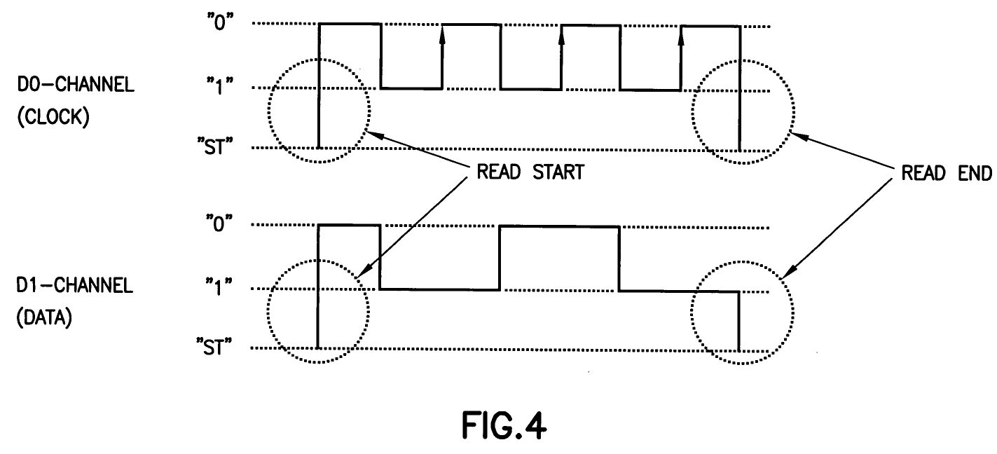

An additional function that can be implemented in accordance with this invention is a read function using one channel (e.g., channel D0) to convey a clock signal and the other channel (D1) to convey data. The read operation is initialized by sending a special command to a slave peripheral (e.g., the display 14 of FIG. 1A), which indicates that the slave is to change its operational mode to the read mode. As is shown in FIG. 4, the master device (e.g., the cellular engine 12 of FIG. 1A) then begins to transmit the clock signal in channel D0, and the slave peripheral places the data in the other channel (D1). The clock signal generated by the master is realized by toggling the signal between the ‘1’ and ‘0’ states, and the data out from the slave is presented as well using the ‘1’ and ‘0’ states. On the rising edge of the clock signal the master device samples the state of the D1 channel, and reads the state as either being a logic zero bit or a logic one bit. When the read operation is completed, the master device sets the state in the channel D0 to the strobe state (ST), and the slave peripheral sets the state of the other channel (D1 in this case) also to the strobe state.

In the preferred embodiment the clock state is controlled by the master device. However, in other embodiments the clock state could be controlled by the slave device to clock data from the master to the slave. In multiple bus embodiments two or more bits can be clocked in parallel during one time cycle.

Based on the foregoing description it should be appreciated that this invention defines exactly a frame start and a frame end and uses fewer pins than a conventional parallel interface. Further, the transmission speed can be significantly higher than conventional serial approaches, as the data rate/number of pins ratio is higher than with existing approaches. In addition, the number of wire (conductors) and the current consumption can be equivalent to existing approaches.

The foregoing description has provided by way of exemplary and non-limiting examples a full and informative description of the best method and apparatus presently contemplated by the inventors for carrying out the invention. However, various modifications and adaptations may become apparent to those skilled in the relevant arts in view of the foregoing description, when read in conjunction with the accompanying drawings and the appended claims. As but some example, other similar or equivalent data representation schemes can be used, other color representation schemes can be used (other than RGB), and the use of more than four channels can be attempted by those skilled in the art. However, all such and similar modifications of the teachings of this invention will still fall within the scope of this invention.

Furthermore, some of the features of the present invention could be used to advantage without the corresponding use of other features. As such, the foregoing description should be considered as merely illustrative of the principles of the present invention, and not in limitation thereof.

1. A Multi-level Analog Signaling (MAS) method comprising encoding data bits represented by multi-level analog signals; transmitting the encoded data bits over at least two multi-level signal buses between a transmitter and a receiver such that, on each multi-level signal bus, during each data bit period the signal level is required to change from a first signal level to a second, different signal level; and indicating a data boundary to the receiver by holding one of the multi-level signal buses at the same level for at least two consecutive bit periods.

2. A method as in claim 1, where encoding includes, when a data bit to be encoded is the same as the data bit encoded for an immediately prior bit period, encoding instead a strobe signal represented by a predetermined one of the levels of the multi-level analog signal, where the presence of the strobe signal at the receiver is used to generate a clock edge.

3. A method as in claim 2, where the multi-level analog signal comprises a PAM-3 signal, where two analog signal levels convey the encoded data bits and one analog signal level conveys the strobe signal.

4. A method as in claim 1, where the data boundary comprises one of the start or the end of a multi-bit frame.

5. A method as in claim 4, where the multi-bit frame comprises at least 24 bits for conveying 8-bit Red, Green and Blue data between the transmitter and the receiver.

6. A method as in claim 4, where the multi-bit frame comprises at least 24 bits for conveying 8-bit Red, Green and Blue data between a control unit of a mobile station and a display of the mobile station.

7. A method as in claim 4, where the multi-bit frame comprises at least 24 bits for conveying 8-bit Red, Green and Blue data between a control unit of a mobile station and a camera of the mobile station.

8. A method as in claim 1, further comprising transmitting a stream of data between the transmitter and the receiver by toggling one of the at least two multi-level signal buses between first and second signal levels to generate clock edges, and setting, so as to coincide with a generated clock edge, a signal level of another one of the at least two multi-level signal buses at a signal level representative of a logic zero signal level or a logic one signal level.

9. A method as in claim 8, where the receiver of the stream of data performs toggling the one of the at least two multi-level signal buses between the first and the second signal levels to generate clock edges.

10. A method as in claim 8, where a beginning and an end of the stream of data is signaled by setting at least one of the different signal buses to a third signal level.

11. A Multi-level Analog Signaling (MAS) circuit arrangement comprising a transmitter to encode data bits represented by multi-level analog signals; at least two multi-level signal buses coupled between said transmitter and a receiver for conveying the encoded data bits such that, on each multi-level signal bus, during each data bit period the signal level is required to change from a first signal level to a second, different signal level; said transmitter indicating a data boundary to said receiver by holding one of the multi-level signal buses at the same level for at least two consecutive bit periods.

12. A (MAS) circuit arrangement as in claim 11, where said transmitter operates to encode data bits such that, when a data bit to be encoded is the same as the data bit encoded for an immediately prior bit period, the transmitter instead encodes a strobe signal represented by a predetermined one of the levels of the multi-level analog signal, where the presence of the strobe signal at said receiver is used to generate a clock edge.

13. A (MAS) circuit arrangement as in claim 12, where the multi-level analog signal comprises a PAM-3 signal, where two analog signal levels convey the encoded data bits and one analog signal level conveys the strobe signal.

14. A (MAS) circuit arrangement as in claim 11, where the data boundary comprises one of the start or the end of a multi-bit frame.

15. A (MAS) circuit arrangement as in claim 14, where the multi-bit frame comprises at least 24 bits for conveying 8-bit Red, Green and Blue data between said transmitter and said receiver.

16. A (MAS) circuit arrangement as in claim 14, where the multi-bit frame comprises at least 24 bits for conveying 8-bit Red, Green and Blue data between a control unit of a mobile station and a display of the mobile station.

17. A (MAS) circuit arrangement as in claim 14, where the multi-bit frame comprises at least 24 bits for conveying 8-bit Red, Green and Blue data between a control unit of a mobile station and a camera of the mobile station.

18. A (MAS) circuit arrangement as in claim 11, where said transmitter and said receiver cooperate to transmit a stream of data by toggling one of the at least two multi-level signal buses between first and second signal levels to generate clock edges, and by setting, so as to coincide with a generated clock edge, a signal level of another one of the at least two multi-level signal buses at a signal level representative of a logic zero signal level or a logic one signal level.

19. A (MAS) circuit arrangement as in claim 18, where said receiver of the stream of data toggles the one of the at least two multi-level signal buses between the first and the second signal levels to generate clock edges.

20. A (MAS) circuit arrangement as in claim 18, where a beginning and an end of the stream of data is signaled by setting at least one of the different signal buses to a third signal level.

21. A mobile station comprising a plurality of sub-assemblies coupled together by a plurality of data communication buses connected to ports, where at least one port comprises a Multi-level Analog Signaling (MAS) circuit arrangement comprising a transmitter to encode data bits represented by multi-level analog signals; where a data communications bus that couples the transmitter to a receiver in another port comprises at least two multi-level signal buses for conveying the encoded data bits such that, on each multi-level signal bus, during each data bit period the signal level is required to change from a first signal level to a second, different signal level; said transmitter indicating a data boundary to said receiver by holding one of the multi-level signal buses of the at least two multi-level signal buses at the same level for at least two consecutive bit periods.

22. A mobile station as in claim 21, where said transmitter operates to encode data bits such that, when a data bit to be encoded is the same as the data bit encoded for an immediately prior bit period, the transmitter instead encodes a strobe signal represented by a predetermined one of the levels of the multi-level analog signal, where the presence of the strobe signal at said receiver is used to generate a clock edge.

23. A mobile station as in claim 22, where the multi-level analog signal comprises a PAM-3 signal, where two analog signal levels convey the encoded data bits and one analog signal level conveys the strobe signal.

24. A mobile station as in claim 21, where the data boundary comprises one of the start or the end of a multi-bit frame.

25. A mobile station as in claim 24, where the multi-bit frame comprises at least 24 bits for conveying 8-bit Red, Green and Blue data between said transmitter and said receiver.

26. A mobile station as in claim 24, where the multi-bit frame comprises at least 24 bits for conveying 8-bit Red, Green and Blue data between a cellular engine of said mobile station and a display of said mobile station.

27. A mobile station as in claim 24, where the multi-bit frame comprises at least 24 bits for conveying 8-bit Red, Green and Blue data between a cellular engine of said mobile station and a camera of said mobile station.

28. A mobile station as in claim 21, where said transmitter and said receiver cooperate to transmit a stream of data by toggling one of the at least two multi-level signal buses between first and second signal levels to generate clock edges, and by setting, so as to coincide with a generated clock edge, a signal level of another one of the at least two multi-level signal buses at a signal level representative of a logic zero signal level or a logic one signal level.

29. A mobile station as in claim 28, where said receiver of the stream of data toggles the one of the at least two multi-level signal buses between the first and the second signal levels to generate clock edges.

30. A mobile station as in claim 28, where a beginning and an end of the stream of data is signaled by setting at least one of the different signal buses to a third signal level.

31. A mobile station as in claim 21, where one of said sub-assemblies comprises a cellular engine that is coupled to circuitry external to said mobile station via another port and data communications bus.

32. Circuitry comprising transmitter means comprising means for encoding data bits represented by multi-level analog signals; at least two multi-level signal bus means coupled between said transmitter means and receiver means for conveying the encoded data bits such that, on each multi-level signal bus means, during each data bit period the signal level is required to change from a first signal level to a second, different signal level; said transmitter means indicating a data boundary to said receiver means by holding one of the multi-level signal buses at the same level for at least two consecutive bit periods.

33. Circuitry as in claim 32, where said encoding means operates to encode data bits such that, when a data bit to be encoded is the same as the data bit encoded for an immediately prior bit period, said encoding means instead encodes a strobe signal represented by a predetermined one of the levels of the multi-level analog signal, where the presence of the strobe signal at said receiver means is used to generate a clock edge.

34. Circuitry as in claim 33, where the multi-level analog signal comprises a PAM-3 signal, where two analog signal levels convey the encoded data bits and one analog signal level conveys the strobe signal.
